(19) United States
(12) Patent Application Publication
(10) Pub. No.: US 2007/0018731 A1
(43) Pub. Date: Jan. 25, 2007

(54) Device for setting a frequency

(76) Inventors: Christophe Casenave, Ulm (DE); Reinhard Monno, Mengerskirchen (DE)

Correspondence Address: BELL, BOYD & LLOYD, LLC, P. O. BOX 1135, CHICAGO, IL, 60690-1135, US

(21) Appl. No.: 10/558,808

(22) PCT Filed: Apr. 7, 2004
(86) PCT No.: PCT/EP04/50478

§ 371 Date: May 12, 2006

(30) Foreign Application Priority Data
May 28, 2003 (DE) 10324392.5

(51) Int. Cl. H03L 7/085

(52) U.S. Cl. 331/1 A

(57) ABSTRACT

The present disclosure relates to a digitally controlled oscillator circuit including a resonant circuit with the following features: an oscillating element for generating an oscillation with a specific high precision frequency and a setting device that is connected to the oscillating element for modifying the oscillation frequency of the oscillating element. The setting device includes the following components: a digitally controllable first capacitance bank, in which a plurality of first setting capacitors are connected in parallel to one another and can be controlled individually in order to set a predefined first total capacitance; and a fine tuning circuit, which is connected in parallel to the first capacitance bank and a first capacitor that is connected in series to a parallel connection between a second capacitor and a digitally controllable second capacitance bank, in which a plurality of capacitors are connected in parallel to one another can be controlled individually in order to set a predefined second total capacitance.

### FIELD OF TECHNOLOGY

The present disclosure relates to a device for generating or setting a frequency. It relates in particular to an oscillator circuit for generating an oscillation with a high level of precision or resolution. Such devices are used in particular for setting frequencies in mobile radio arrangements, e.g. mobile telephones.

### BACKGROUND

Oscillators or clock generators are required in many electronic devices, in particular telecommunication devices such as mobile telephones. They are used, for example, to generate transmit signals, to manipulate other signals or to clock processors. An oscillator generates a signal that changes within a defined clock pulse with a defined repetition rate or the frequency. It is frequently necessary to be able to set this frequency very precisely. With conventional analog controlled oscillators, this setting functionality is achieved by means of an analog control signal (voltage, current, . . . ), which modifies parameters in the electronic circuit. However oscillators, in which elements in the circuit are switched or disconnected, have also been used for some time. As the elements (e.g. capacitors) then cannot pass through any intermediate values, the frequency can only be set in specific steps and is not continuous. This causes problems in many systems, if the steps are too large. These oscillators are known as digitally controlled oscillators(DCO). Frequency setting in this manner is described in more detail below.

In mobile radio arrangements it is important to generate frequencies as carrier frequencies for data signals (which are modulated up to the carrier frequency) with a high level of frequency precision. For example, a mobile station must be able to set the frequency required by a base station when prompted in order to establish a good communication connection. To this end an oscillator circuit or oscillator is provided in the mobile telephone, which is able to generate a frequency or carrier frequency with a high level of precision, with the possibility of setting the frequency of the oscillator.

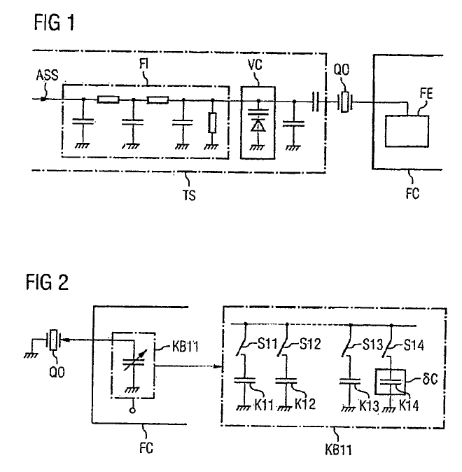

An example of an oscillator circuit or an oscillator, as used in a mobile telephone or generally in a mobile radio device, is shown in FIG. 1. A quartz element QO is thereby shown in the center of the circuit, which is designed to generate oscillations with high-precision frequency. The frequency generated by the oscillator circuit or quartz element QO thereby serves as the reference frequency for subsequent frequency processing devices. In the case of a mobile telephone operating according to the GSM (Global Standard for Mobile Communications) standard, the generated frequency can be 26 MHz±2.6 Hz. In the example, the generated frequency is supplied to radio device FE, on a radio chip FC. In the radio device FE the frequency is in some instances fed to a multiplication device or a frequency multiplier (not shown), to generate a frequency with a multiple value after corresponding multiplication. In the example of a mobile telephone operating according to the GSM standard, the multiplied frequency should be 900 MHz as the carrier frequency for data signals. A radio signal is then generated by means of the radio device or an antenna connected thereto (not shown) based on the generated multiplied carrier frequency to a base station, which sends back a radio signal if required, prompting the mobile telephone to modify or adjust the frequency or carrier frequency. Such a prompt is processed by the radio device FE of the mobile telephone, to start a process to adjust the carrier frequency.

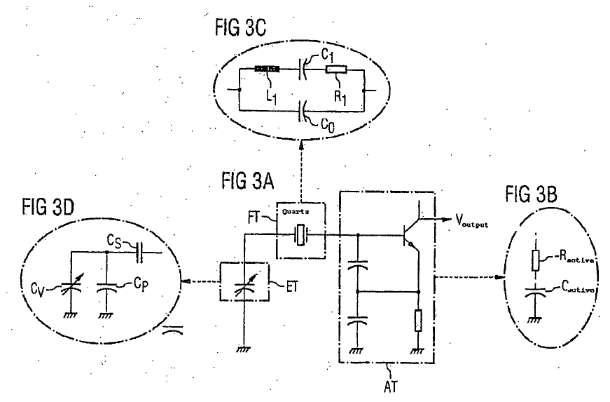

The radio device FE or a control device connected thereto thereby generates an analog control signal(ASS), which is fed to a setting circuit or tuning circuit TS (shown by the arrow on the left side of the figure), which is connected to the quartz element. In the process this analog control signal ASS passes first through a filter section FI of the tuning circuit TS, comprising a plurality of resistors and capacitors, to filter out external interference for example. The analog control signal is then fed to the central element of the tuning circuit, namely a varicap or varacter diode (capacitance diode) VC with voltage-controlled capacitance. Setting the capacitance at the varicap VC by means of the analog control signal allows the oscillation of the quartz element to be influenced such that the frequency of the oscillator circuit as a whole (in the example here to generate a multiplied carrier frequency) is modified (see also FIG. 3 for a further explanation) to comply with the prompt from the base station.

The analog generation or correction of the control voltage for the quartz oscillator by means of the tuning circuit described above has the advantage of allowing correction with any level of precision or in a continuous fashion and also allows precise frequency setting at the quartz oscillator. However, the circuit has a high level of sensitivity to interference because of the analog control signal used, and the high costs of the tuning circuit, in particular the varicap VC, that is arranged externally in relation to the radio chip FC are disadvantageous.

### SUMMARY

Instead of an external tuning circuit TS, i.e. a tuning circuit that is not provided on the radio chip, it is also possible to provide a tuning circuit to generate a control signal or a control voltage on the radio chip, allowing a digital frequency correction. An embodiment of a quartz oscillator or its circuit is shown to this end in FIG. 2, where the tuning circuit is provided in the radio chip.

According to FIG. 1 a quartz element QO is provided, which is designed to generate an oscillation with a high-precision frequency. If the frequency generated by the quartz element or the oscillator circuit then has to be modified (e.g., the carrier frequency has to be adjusted to a value required by a basestation), the adjustment is no longer carried out by means of an analog tuning circuit as in FIG. 1 but by means of a digitally controllable capacitance bank KB11. The capacitance bank KB11 thereby comprises a plurality of capacitors K11 to K14 connected in parallel, which can be connected or disconnected individually to achieve a first total capacitance of a defined value. This connection or disconnection takes place by means of a switch S11 to S14 assigned to each capacitor K11 to K14. The radio device FE or a control device (not shown) thereby sends a digital programming word or correction word to the capacitance bank KB11, in which corresponding capacitors are then connected or disconnected. The oscillation of the quartz element QO is then influenced as a function of the first total capacitance thus generated such that modification or adjustment of the frequency generated by the quartz oscillator QO then results.

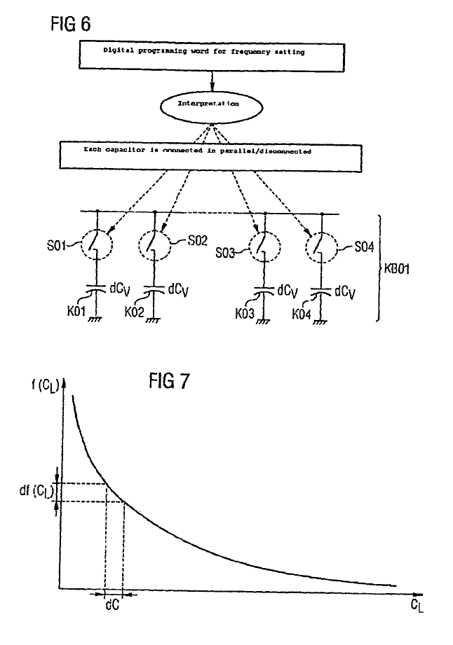

The aforementioned arrangement for digital frequency correction of a quartz oscillator has a low level of sensitivity to interference and can be produced at low cost, as all the components used for the oscillator circuit (including the quartz oscillator) can be provided on the radio chip. During the generation of a control capacitance by the capacitance bank KB11, discrete or quantized frequencies or frequency changes can be generated due to the discrete or quantized changes 6C of the (first) total capacitance on connection or disconnection of a setting capacitor K11 to K14 with a capacitance δC. Precise setting of the frequency generated by the quartz oscillator QO is not possible with the digital frequency correction shown in FIG. 2 (see also FIG. 6 for a further explanation).

A digitally controlled oscillator circuit preferably has at least one frequency-defining component to generate an oscillation with a defined high-precision frequency. This can be an oscillating element, such as a quartz element. The oscillator circuit also has a setting device connected to the frequency-defining component to modify the oscillation frequency of the oscillator circuit. The setting device preferably has a digitally controllable first reactance bank, in which a plurality of first setting reactances are connected together and can be controlled individually to set a predefined first total reactance. The connection can be a parallel or series circuit. It should be noted that a reactance refers to a resistance of the alternating current, which is only brought about by inductive and/or capacitive resistance and here represents a generalization of a capacitance or a capacitor and/or an inductance or a coil. The setting device also has a fine tuning circuit, which is connected to the first reactance bank and has a first reactance, which is connected in series to a parallel circuit comprising a second reactance and a digitally controllable second reactance bank, in which a plurality of second setting reactances are connected together and can be controlled individually to set a predefined second total reactance.

According to an exemplary embodiment, the setting device has a digitally controllable first capacitance bank (as the first reactance bank), in which a plurality of first setting capacitors (as first setting reactances) are connected together and can be controlled individually, to set a predefined first total capacitance (as the first total reactance). The setting device also has a fine tuning circuit, which is connected to the first capacitance bank, and a first capacitor (as the first reactance), which is connected in series to a parallel circuit comprising a second capacitor (as the second reactance) and a digitally controllable second capacitance bank (as the second reactance bank), in which a plurality of second setting capacitors (as second setting reactances) are connected together and can be controlled individually to set a predefined second total capacitance (as the second total reactance).

Correspondingly, according to a further embodiment, the setting device is arranged having a digitally controllable first inductance bank (as the first reactance bank), in which a plurality of first setting inductances (as first setting reactances) are connected together and can be controlled individually to set a predefined first total inductance (as the first total reactance). The setting device also has a fine tuning circuit, which is connected to the first capacitance bank and has a first inductance (as the first reactance), which is connected in series to a parallel circuit comprising a second inductance (as the second reactance) and a digitally controllable second inductance bank (as the second reactance bank), in which a plurality of second setting inductances (as second setting reactances) are connected together and can be controlled individually to set a predefined second total inductance (as the second total reactance). The setting inductances can thereby include coils, resonant circuits or lines with defined inductance.

The digitally controlled oscillator circuit according to the present disclosure has the following advantages:

a) Frequency correction in the resonant circuit of the oscillator takes place digitally and is therefore independent of D/A (digital-analog) converter characteristics (e.g. the response to supply voltage dips).

b) A programming word can be sent digitally to the capacitance banks of the setting device, bringing about a high level of insensitivity to interference. Filtering (as with analog frequency correction) can be omitted.

c) As all the components of the oscillator circuit can be provided on a chip, savings result in respect of space, components and cost, as well as fitting costs.

d) Total integration in an integrated switching circuit reduces the development time for the oscillator circuit in an electrical device.

Use of the fine tuning circuit in the setting device means that almost any resolution can be achieved and therefore the frequency can be set very precisely.

According to a further embodiment an electrical device is disclosed having an oscillator circuit. The electrical device includes a radio module or a radio device, in which the oscillator circuit is provided in particular to generate a frequency as a basis for a carrier frequency for a radio signal. The electrical device can thereby be configured as a (portable) computer or as a mobile radio device, in particular a mobile telephone. The radio module or mobile radio device can operate according to the GSM (Global System for Mobile Communications), UMTS (Universal Mobile Telecommunications System), DECT (Digital Enhanced Cordless Telecommunications), WLAN (Wireless Local Area Network) or CDMA (Code Division Multiple Access) standard.

### DETAILED DESCRIPTION OF THE DRAWINGS

The various objects, advantages and novel features of the present disclosure will be more readily apprehended from the following Detailed Description when read in conjunction with the enclosed drawings, in which:

FIG. 1 illustrates a circuit for generating and setting the frequency by means of analog frequency correction;

FIG. 2 illustrates a circuit for generating and setting a frequency by means of digital frequency correction;

FIG. 3 illustrates a circuit for generating and setting a frequency by means of analog frequency correction;

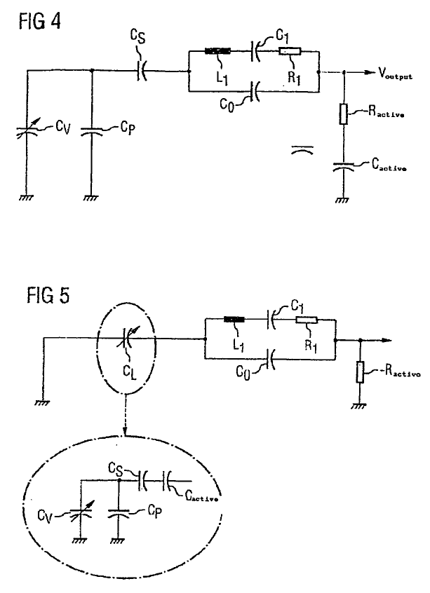

FIG. 4 illustrates a circuit for generating and setting a frequency in the equivalent circuit diagram for the components from FIG. 3;

FIG. 5 illustrates an equivalent circuit diagram from FIG. 4, in which a number of capacitors are combined into one load capacitor CL or one load capacitance;

FIG. 6 schematically illustrates the generation of a digitally controlled variable capacitance, by means of a parallel circuit of a number of small capacitors to earth;

FIG. 7 illustrates a frequency f(CL) as a function of load capacitance CL;

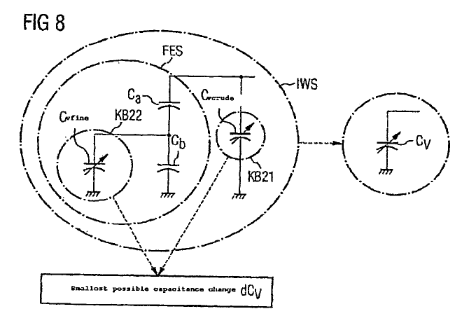

FIG. 8 illustrates a circuit diagram of an impedance converter circuit according to another exemplary embodiment for setting the frequency of an oscillator circuit according to FIG. 5.

### DETAILED DESCRIPTION

Before describing a preferred embodiment of a circuit for generating or setting a frequency by means of an oscillator or an oscillator circuit below, we will first look again at the basic theory of adjustable oscillators or oscillator circuits using the example of a quartz oscillator (CXO: Controlled Crystal Oscillator).

1. Frequency Setting in the Case of Adjustable Oscillators

FIG. 3A again shows the three main elements or main components of a controlled oscillator or an oscillator circuit, which form a resonant circuit or an oscillation system:

a) An active element AT: this acts as a negative resistance and allows oscillation of the system, as it compensates for the resistance of the remainder of the circuit. This active element can be represented with a negative resistance (-R or -Ractive) in series with a capacitor (Cactive) (see FIG. 3B).

b) A frequency-defining element FT (in this instance the quartz): this is generally represented as a series RLC circuit with a parallel capacitor C0. In the case of a quartz oscillator, the quartz parameters R1, C1 and L1 are known with a certain precision (see FIG. 3C).

c) A setting element ET: this is generally provided by an adjustable capacitor (Cv) and some fixed capacitors (in this instance Cs and Cp) to center the circuit (see FIG. 3D). This adjustable capacitor can be set by an analog signal (as described above in respect of FIG. 1), generally a voltage (in this instance a VC(X)O or Voltage Controlled (Crystal) Oscillator) or by a digital signal, as described in more detail below.

FIG. 4 shows the quartz oscillator circuit described above with equivalent components.

If the capacitors Cv, Cp, Cs and Cactive are combined, as in FIG. 5, the illustration of the oscillator or oscillator circuit can be simplified. The oscillating element is now connected in series to a capacitance or load capacitance CL. CL is a function of Cv, Cp, Cs and Cactive. In this specific instance CL can be calculated on the basis of FIG. 4 as (equation 1):

$${C}_{L} = \frac{( {C}_{v} + {C}_{p} ) \cdot {C}_{s} {C}_{active}}{( {C}_{v} + {C}_{p} ) \cdot ( {C}_{s} + {C}_{active} ) + {C}_{s} {C}_{active}} \qquad ( 1 )$$

If we describe the natural frequency of the quartz as f₀=(2π\sqrt{L₁·C₁})⁻¹ the frequency f1 at which the circuit can oscillate can now be expressed as a function of CL (equation 2):

$$f ( {C}_{L} ) = {f}_{0} \cdot ( 1 + \frac{{C}_{1}}{2 \cdot ( {C}_{0} + {C}_{L} )} ) \qquad ( 2 )$$

Such a function of the frequency f of the load capacitance CL is shown in FIG. 7.

The frequency f of the oscillator circuit can be set by modifying the load capacitance CL and because CL itself is a function of Cv, by modifying the adjustable capacitance Cv.

2. Provision of a Digitally Controlled Oscillator Circuit

The general provision of an adjustable capacitance Cv, as described above, is explained below.

One principle for generating a capacitor with a variable capacitance is shown with reference to FIG. 6. For example by connecting a number of capacitors K01 to K04 with small capacitances dCv in parallel, it is possible to generate a larger capacitance or total capacitance Cv. Such a parallel circuit is also referred to as a capacitance bank KB01 (see also FIG. 2 relating to the capacitance bank KB11 with the respective setting capacitors K11 to K14). When it is possible to program the switching by means of switches S01 to S04 of every individual capacitance or every individual capacitor (by means of a programming word), the value of the large capacitance Cv becomes variable.

For the explanations which follow it is assumed that the capacitance bank KB01 has a total capacitance Cv, which can be changed or set by connecting or disconnecting the individual capacitances dCv.

Frequency precision may be arranged to be a function of the smallest achievable capacitance dCv. If frequency is seen as a function of the total load capacitance CL (see equation 2 and FIG. 7), the following results for frequency precision df(C_{L}):

$$df ( {C}_{L} ) = ( \frac{\partial f}{\partial {C}_{L}} ) \cdot {dC}_{L}$$

The value dCL here is the precision that can be achieved for the value of total load capacitance. Because CL is a function of Cv, the following also applies:

$${dC}_{L} ( {C}_{v} ) = ( \frac{\partial {C}_{L}}{\partial {C}_{V}} ) \cdot {dC}_{v}$$

These two equations give the frequency precision as a function of the total load capacitance CL(Cv) and the capacitance step of the capacitance bank dC, (equation 3):

$$df ( {C}_{v} ) = ( \frac{\partial f}{\partial {C}_{L}} ) \cdot ( \frac{\partial {C}_{L}}{\partial {C}_{v}} ) \cdot {dC}_{v} \qquad ( 3 )$$

In the present example of an oscillator circuit according to FIGS. 3 and 5 the next two equations can be written as follows:

$$\frac{\partial f}{\partial {C}_{L}} = - \frac{{f}_{0} \cdot {C}_{1}}{2 \cdot {( {C}_{0} + {C}_{L} )}^{2}}$$

$$\frac{\partial {C}_{L}}{\partial {C}_{V}} = {( \frac{{C}_{s} \cdot {C}_{active}}{( {C}_{v} + {C}_{p} ) \cdot ( {C}_{s} + {C}_{active} ) + {C}_{s} \cdot {C}_{active}} )}^{2}$$

The following calculation example should be considered to give an idea of magnitude. It is used to calculate the frequency precision of the circuit when Cv=10 pF, dCv=2 fF and the quartz parameters have the following magnitude:

f0=25992606 Hz

C1=6.6 fF

C0=1.6 pF

Thus, the circuit is dimensioned:

Cp=4 pF

Cs=Cactive=40 pF

In this instance the following results:

$$\begin{matrix}{C}_{L} = 8.24 pF \\ \frac{\partial f}{\partial {C}_{L}} ( {C}_{L} ) = 1773.45 Hz / pF \\ \frac{\partial {C}_{L}}{\partial {C}_{v}} ( {C}_{v} ) = 0.346\end{matrix} \} ⇒ df ( {C}_{v} = 10 pF ) = 1.22 Hz$$

There are however instances (for example in a mobile radio arrangement, such as a mobile telephone operating according to the GSM standard), in which this precision is not sufficient. Attempts can then be made to optimize the quartz parameters or other values in the circuit but the margin is often very narrow.

Attempts can also be made to reduce the value of the capacitance dCv, Unfortunately this is sometimes impossible due to the technology. In such instances a solution can be used according to an embodiment of the invention described below.

3. Increased Precision Through the Use of an Impedance Converter

The (simple) capacitance bank KB01 described above with the variable capacitance Cv is now replaced by an impedance converter circuit (IWS) with two capacitance banks, namely a first capacitance bank KB21 with an adjustable capacitance Cvcrude and a second capacitance bank KB22 with an adjustable capacitance Cvfine. It should be noted here that the structure (parallel circuit of setting capacitors) and the mode of operation of each of the new capacitance banks correspond to those of the capacitance bank KB01 (or the capacitance bank KB11 in FIG. 2). The switching of the impedance converter circuit is shown in FIG. 8. The capacitor Ca, the capacitor Cb and the second capacitance bank KB22 thereby form a fine tuning device or fine tuning circuit FES, as described in greater detail below. For each of the two banks the best achievable precision dCv of a capacitance change is limited to the minimum achievable capacitance dCvmin of a capacitor or setting capacitor by the technology (during capacitor production) or the number of capacitors in the capacitance bank. In most instances the capacitance Cvcrude is dimensioned such that the required frequency pulling range f(Cvcrudemax)−f(Cvcrudemin) is achieved with a mean level of precision. Fine precision is then achieved here by the combination of Cvfine, Ca and Cb.

The equivalent capacitance or total capacitance of the impedance converter circuit IWS is now referred to as Cv and can be calculated as follows (equation 4):

$$\begin{matrix}{C}_{v} = {C}_{vcrude} + \frac{{C}_{a} ( {C}_{b} + {C}_{vfine} )}{{C}_{a} + {C}_{b} + {C}_{vfine}} \\ = {C}_{vcrude} + \frac{( \frac{{C}_{a} {C}_{b}}{{C}_{a} + {C}_{b}} + \frac{{C}_{vfine}}{{C}_{a} + {C}_{b}} ) \cdot {( 1 + \frac{{C}_{a} {C}_{vfine}}{{C}_{a} + {C}_{b}} )}^{- 1}}{{C}_{add} ( {C}_{a} \cdot {C}_{b} \cdot {C}_{vfine} )}\end{matrix} \qquad ( 4 )$$

It can be seen that Cv results from the sum of a crude capacitance Cvcrude and a more finely quantized capacitance Cadd.

If ΔC_{add}=C_{add}(C_{vfine max})−C_{add}(C_{vfine min}) is the maximum capacitance range that the capacitance Cadd must cover, it is in most instances desirable for the following to apply:
0≦ΔC_{add}≦dC_{vcrude}.

It is expedient here to select Ca+Cb [symbol] Cvfine. It is then possible to simplify Cv with an approximation as follows (equation 5):

$${dC}_{v} = ( \frac{\partial {C}_{v}}{\partial {C}_{vfine}} ) \cdot {dC}_{vfine} \qquad ( 5 )$$

Equation 5 shows that Cv can be used in a linear fashion by means of an appropriate selection of Ca and Cb. Then precisely one step of Cvcrude corresponds to the capacitance range transformed by Ca and Cb. This was done under point 2. It only remains to demonstrate that precision has improved.

If Cvfine is switched by a small step or capacitance step dCvfine, for dCv this corresponds to a step of:

$${dC}_{v} = ( \frac{\partial {C}_{v}}{\partial {C}_{vfine}} ) \cdot {dC}_{vfine}$$

Deriving from equation 4 gives (equation 6):

$$\begin{matrix}{dC}_{v} = {( \frac{{C}_{a}}{{C}_{a} + {C}_{b} + {C}_{vfine}} )}^{2} \cdot {dC}_{vfine} \\ = {( \frac{{C}_{a}}{{C}_{a} + {C}_{b}} )}^{2} \cdot {( 1 + \frac{{C}_{vfine}}{{C}_{a} + {C}_{b}} )}^{- 2} \cdot {dC}_{vfine}\end{matrix} \qquad ( 6 )$$

To achieve a fine resolution, Ca and Cb would have to be selected such that Ca+Cb [symbol] Cvfine. Equation 6 can then be written as follows:

$${dC}_{v} \sim {( \frac{{C}_{a}}{{C}_{a} + {C}_{b}} )}^{2} ( 1 - 2 \cdot \frac{{C}_{vfine}}{{C}_{a} + {C}_{b}} ) \cdot {dC}_{vfine} \qquad ( 7 )$$

This can be simplified further to (equation 8):

$${dC}_{v} \sim {( \frac{{C}_{a}}{{C}_{a} + {C}_{b}} )}^{2} {dC}_{vfine} \qquad ( 8 )$$

The advantageous effects of the impedance converter circuit IWS are now shown in a specific arithmetic example. The technology for producing capacitors allows the production of a setting capacitor in a capacitance bank with a capacitance value of dCvfine=2 fF (=2 femtofarad) as the smallest value. Ca=1 pF and Cb=10 pF are selected. The total capacitance Cv of the impedance converter circuit IWS can then be quantized in steps of dCv, which can be calculated using equation 8. The following ultimately results from this for the effective change in the capacitance of the impedance converter circuit IWS in the event of modification of the capacitance of KB22 by dCvfine: dCv=0.0165 fF. This corresponds to an improvement factor of approximately 121 in resolution compared with the solution with which only one capacitance bank is used to set the load capacitance.

With regard to a practical application of an oscillator circuit, as described with reference to FIGS. 1 and 2, the one oscillator circuit according to an embodiment of the invention, i.e. with a digitally controllable impedance converter circuit IWS, can also be integrated on a radio chip of a mobile telephone. For example the capacitance bank KB11 shown in FIG. 2 could be replaced by the impedance converter circuit IWS. It is however possible to use the oscillator circuit according to an embodiment of the invention in other electrical devices, which require a high-precision frequency in order to be able to operate.

It should be understood that the various changes and modifications to the presently preferred embodiments described herein will be apparent to those skilled in the art. Such changes and modifications can be made without departing from the spirit and scope of the present disclosure and without diminishing its intended advantages. It is therefore intended that such changes and modifications be covered by the appended claims.

1-10. (canceled)

11. A digitally controlled oscillator circuit comprising:
a frequency defining component for generating a high frequency oscillation;
a setting device connected to the frequency defining component to modify the oscillation frequency of the oscillator circuit, the setting device comprising:
a digitally controllable first reactance bank, wherein a plurality of first setting reactances are established and controlled individually to set a predefined first total reactance; and
a fine tuning device connected to the first reactance bank wherein the fine tuning device has a first reactance which is coupled in series to a parallel circuit comprising a second reactance and a digitally controllable second reactance bank, in which a plurality of second setting reactances are established and controlled individually to set a predefined second total reactance.

12. The oscillator circuit according to claim 11, wherein the frequency defining component is a quartz oscillator element.

13. The oscillator circuit according to claim 11, wherein the first and second reactance together comprise a greater reactance than the second total reactance.

14. The oscillator circuit according to claim 11, wherein the first and second reactance bank can be controlled by a digital programming word, and wherein respective reactance settings are connected or disconnected as a function of the programming word.

15. The oscillator circuit according to claim 11, wherein the first and second reactance bank is a capacitance bank, in which a plurality of setting capacitors are connected together as setting reactances and can be controlled individually to set a defined total capacitance as a total reactance.

16. The oscillator circuit according to claim 11, wherein the first and second reactance bank is an inductance bank, in which a plurality of setting inductances are connected together as setting reactances and can be controlled individually to set a predefined total inductance as a total reactance.

17. The oscillator circuit according to claim 16, wherein the setting inductances are one of coils, resonant circuits and lines with defined inductance.
